(19) United States
(12) Patent Application Publication
(10) Pub. No.: US 2014/0292336 A1
(43) Pub. Date: Oct. 2, 2014

(54) APPARATUS AND METHOD FOR MEASURING FREE RADICALS

(71) Applicant: Electronics and Telecommunications Research Institute, Daejeon (KR)

(72) Inventor: Hyo Bong HONG, Daejeon (KR)

(73) Assignee: Electronics and Telecommunications Research Institute, Daejeon (KR)

(21) Appl. No.: 13/962,299

(22) Filed: Aug. 8, 2013

(30) Foreign Application Priority Data
Apr. 1, 2013 (KR) 10-2013-0035424

(51) Int. Cl. G01R 33/60

(52) U.S. Cl. CPC G01R 33/60
USPC 324/316; 324/322

(57) ABSTRACT

A double solenoid coil operates in accordance with input first and second signals to generate an electromagnetic field and to provide the generated electromagnetic field as a sample. Then, a signal corresponding to the generated electromagnetic field is received, amplified, and output by a double lock-in amplifier. Free radicals generated by the sample in accordance with the electromagnetic field are measured based on the signal output from the double lock-in amplifier.

### CROSS-REFERENCE TO RELATED APPLICATION

This application claims priority to and the benefit of Korean Patent Application No. 10-2013-0035424 filed in the Korean Intellectual Property Office on Apr. 1, 2013, the entire contents of which are incorporated herein by reference.

### BACKGROUND OF THE INVENTION

(a) Field of the Invention

The present invention relates to a measuring apparatus and a measuring method. More particularly, the present invention relates to an apparatus and a method for measuring free radicals.

(b) Description of the Related Art

It is very important to utilize and develop an apparatus for analyzing a paramagnetic or super-paramagnetic material such as free radicals in fields such as biotechnology, medicine, and chemistry.

Such an analyzing apparatus may be divided into 1) a part for generating a signal, 2) a part for securing, amplifying, and processing a signal, and 3) a part for storing a signal to be actually processed by a person. Among the above parts, in a case of the part for generating the signal, a basic physical law is well known and a degree to which performance of a system is improved is limited excluding a change in a size or an output. However, in cases of the parts related to 2) and 3), due to development of new electronic and mechanical equipment, a degree to which performance of a system is improved is large.

An electron spin resonance (ESR) apparatus is used as the analyzing apparatus. The ESR apparatus is an apparatus for analyzing an electromagnetic field by combining a Helmholtz coil and a modulation coil.

Currently developed ESR apparatuses vary between companies that manufacture equipment. However, basic forms of ESR spectrometers are almost the same. In most cases, microwaves are generated by a Krystone tube or an autodyne tube, a magnetic force is swept by a Helmholtz coil to find an optimal absorbing point, and the optimal absorbing point is primarily differentiated to output an ESR signal.

A method of using the Helmholtz coil and a specific frequency (mainly microwaves) as a basic structure for securing the ESR signal hardly changes. Most current ESR related technologies are about using a frequency other than microwaves, efficiently using the Helmholtz coil, and how to combine the above two factors.

However, there has not been a large amount of studies on a method of generating the two factors, and the conventional ESR apparatus uses the expensive Helmholtz coil and has a complicated structure.

### SUMMARY OF THE INVENTION

An object of the present invention is to provide an apparatus for measuring free radicals with a simple structure and a method of measuring free radicals.

A measuring apparatus according to one aspect of the present invention includes a signal generator for generating a first signal and a second signal having different frequencies, a double solenoid coil for operating in accordance with the first signal and the second signal to generate an electromagnetic field and to provide the generated electromagnetic field as a sample, a first amplifier for receiving a signal corresponding to the generated electromagnetic field to amplify and output the received signal, a second amplifier for amplifying the signal output from the first amplifier to output the amplified signal, and a measuring unit for receiving a signal from the second amplifier to measure the received signal.

The first amplifier and the second amplifier may form a double lock-in amplifier. The measuring unit may measure free radicals generated by the sample in accordance with an electromagnetic field based on a signal corresponding to the electromagnetic field.

The measuring apparatus may further include a spectrum analyzing unit for analyzing a frequency spectrum of a signal corresponding to an electromagnetic field generated by the double solenoid coil.

A measuring method according to another aspect of the present invention includes a double solenoid coil operating in accordance with input first and second signals to generate an electromagnetic field and to provide the generated electromagnetic field as a sample, receiving, amplifying, and outputting a signal corresponding to the generated electromagnetic field by a double lock-in amplifier, and measuring free radicals generated by the sample in accordance with an electromagnetic field based on the signal output from the double lock-in amplifier.

The measuring method may further include analyzing a frequency spectrum of a signal corresponding to an electromagnetic field generated by the double solenoid coil to analyze a state of free radicals. According to an exemplary embodiment of the present invention, a signal for measuring free radicals may be generated by the double solenoid coil and the lock-in amplifier, and free radicals may be measured using the signal.

### BRIEF DESCRIPTION OF THE DRAWINGS

FIG. 1 is a view illustrating a structure of a free radical measuring apparatus according to an exemplary embodiment of the present invention, and

FIG. 2 is a view illustrating a signal flow in a free radical measuring apparatus according to an exemplary embodiment of the present invention.

FIG. 3 is a flowchart of a free radical measuring method according to an exemplary embodiment of the present invention.

FIG. 4 is a graph illustrating a free radical measuring result according to an exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In the entire specification, unless explicitly described to the contrary, the word “comprise” and variations such as “comprises” or “comprising” will be understood to imply the inclusion of stated elements but not the exclusion of any other elements.

Hereinafter, an apparatus and a method for measuring free radicals according to an exemplary embodiment of the present invention will be described with reference to the drawings.

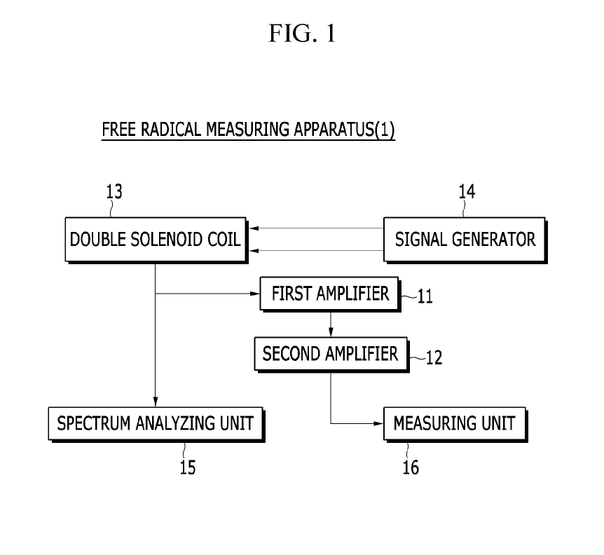

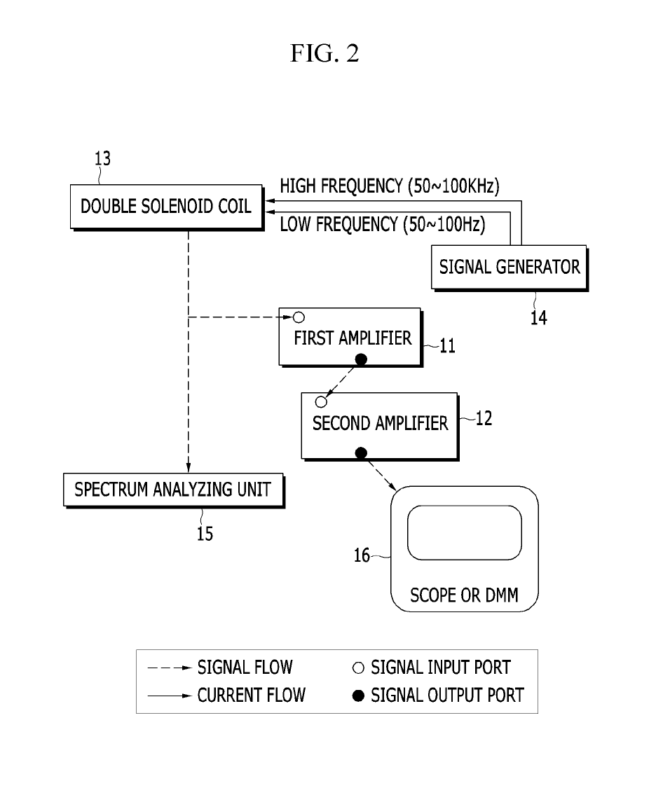

FIG. 1 is a view illustrating a structure of a free radical measuring apparatus according to an exemplary embodiment of the present invention, and FIG. 2 is a view illustrating a signal flow in a free radical measuring apparatus according to an exemplary embodiment of the present invention.

A free radical measuring apparatus 1 (hereinafter, for better comprehension and ease of description, referred to as a measuring apparatus) according to an exemplary embodiment of the present invention generates an electromagnetic field signal for measuring free radicals, and provides the generated electromagnetic field signal as a sample to be measured to measure free radicals generated in accordance with a decomposition reaction in order to provide information on how an arbitrary material (e.g., hydrogen peroxide) is decomposed into free radicals. Here, free radicals include a paramagnetic or super-paramagnetic material.

In order to measure free radicals, as illustrated in FIG. 1, a measuring apparatus 1 according to an exemplary embodiment of the present invention includes a first amplifier 11 and a second amplifier 12, a sensing unit 13, a signal generator 14, a spectrum analyzing unit 15, and a measuring unit 16.

The first amplifier 11 and the second amplifier 12 are formed of lock-in amplifiers (LIA). The first amplifier and the second amplifier may be referred to as “a double lock-in amplifier”. A lock-in amplifier is an amplifier that responses only to an input signal having a frequency synchronized with a frequency of a local oscillation control signal.

An output end of the first amplifier 11 is connected to an input end of the second amplifier 12, and the measuring unit 16 is connected to an output end of the second amplifier 12.

The measuring unit 16 measures an output of the double lock-in amplifier, that is, an output of the second amplifier 12. The measuring unit 16 may be formed of a digital multimeter (DMM), a spectrometer, or an oscilloscope, and measures and analyzes signals received through a plurality of channels.

On the other hand, the signal generator 14 generates a first signal and a second signal for measuring free radicals to output the generated first and second signals. The first signal is a high frequency signal having a frequency of not less than a predetermined frequency, and may be, for example as illustrated in FIG. 2, a signal having a frequency of 50-100 KHz. The second signal is a low frequency signal having a smaller frequency than a predetermined frequency and may be, for example as illustrated in FIG. 2, a signal having a frequency of 50-100 Hz. The signal generator 14 generates the first and second signals having different frequencies to output the generated first and second signals with maximized output power.

A double solenoid coil 13 forms an electromagnetic field corresponding to the input first and second signals. The double solenoid coil 13 forms a mixed electromagnetic field in accordance with the frequency of the first signal and the frequency of the second signal, and the formed electromagnetic field is provided to a sample region. Therefore, a signal capable of measuring free radicals may be secured without an expensive Helmholtz coil or an electromagnet. The double solenoid coil 13 functions as a magnetic field generator.

A sample (e.g., hydrogen peroxide) that generates free radicals may be provided to the sample region. The sample may be in the form of a liquid, solid, and gel. The number of electrons of an outermost electron shell of free radicals is odd. Therefore, since free radicals are paramagnetic, when free radicals are generated in the sample region, a magnetic field may be changed.

The spectrum analyzing unit 15 measures a change in the magnetic field provided to the sample region. Since a spectrum varies with an intensity of the magnetic field, the change in the magnetic field may be measured based on the spectrum.

On the other hand, when a signal in accordance with the electromagnetic field generated by the double solenoid coil 13 is input to the first amplifier 11, the first amplifier 11 amplifies a signal having a frequency synchronized with a frequency of a predetermined local oscillation control signal (a reference signal) to output the amplified signal, and the second amplifier 12 amplifies the signal output from the first amplifier 11 to output a final signal to the measuring unit 16. The measuring unit 16 measures intensity of the magnetic field generated in the sample region based on the signal output from the double lock-in amplifier. A signal for measuring free radical may be secured by the double lock-in amplifier using a double phase shift detection principle.

A method of measuring free radicals will be described based on the measuring apparatus 1 having such a structure.

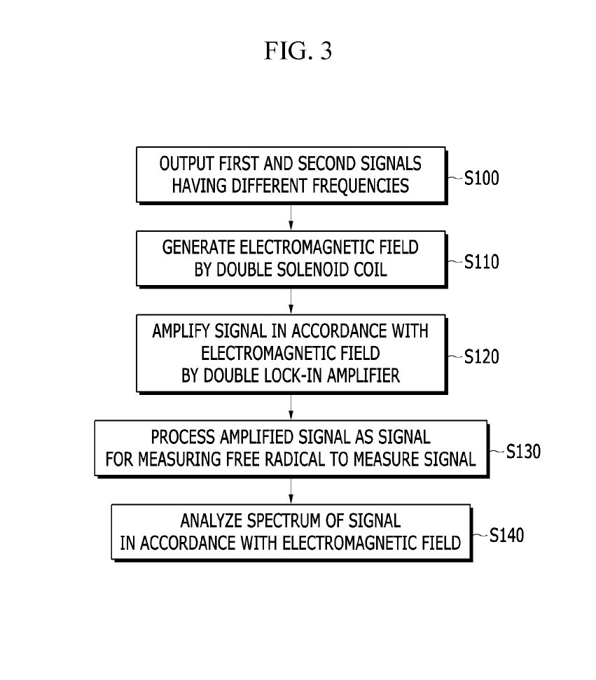

FIG. 3 is a flowchart of a method of measuring free radicals according to an exemplary embodiment of the present invention.

First, in order to measure free radicals, a material to be measured as a sample is provided to the measuring apparatus 1.

As the material to be measured for measuring free radicals, for example, 100 mg of DPPH (2,2-diphenyl-1-picrylhydrazil) is used, and a measurement head obtained by putting 100 mg of DPPH into a glass tube having an interior diameter of 4 mm and an exterior diameter of 5 mm×8.5 cm may be used. One end of a BNC connector (e.g., T shaped) is connected to a signal input end of one of the first amplifier 11 and the second amplifier 12 that are the two lock-in amplifiers of the measuring apparatus 1, and the other end of the BNC connector is connected to a signal input end of the spectrum analyzing unit 15. One end of another BNC connector is connected to a signal input end of the remaining amplifier, and the other end of the BNC connector is connected to a signal input end of the measuring unit 16. Then, a signal for measuring free radicals may be secured by the spectrum analyzing unit 15 and the measuring unit 16.

A frequency of a sine output of the first amplifier 11 and the second amplifier 12 is tuned to 50-100 KHz (or 20-60 KHz), and output power (AMPL) is maximized (e.g., 5 V). An output of the first amplifier 11 is connected to a signal input end of the second amplifier 12 as the other lock-in amplifier.

In order to measure free radicals using the measuring apparatus 1, for example, when the first and second amplifiers (e.g., SR830-1 and SR830-2) having two channels CH1 and CH2 are used, values of the channels are to be minimized before measurement, and this is to be 0 to no less than three decimal places (in units of V). When the signal is secured using the first and second amplifiers, for example, a value of the channel CH2 is not to be shifted while a value of the channel CH1 is shifted. In this case, a frequency or a phase of the reference signal may be controlled.

As described above, in a state where an environment for measuring free radicals is set up, as illustrated in FIG. 3, when the first signal and the second signal are output from the signal generator 14 (S100), the double solenoid coil 13 generates a mixed electromagnetic field corresponding to the input first and second signals (S110).

The first amplifier 11 amplifies the signal corresponding to the generated electromagnetic field to output the amplified signal, and the amplified signal is input to the second amplifier 12 to be amplified and is output to the measuring unit (S120). As a result, the signal in accordance with the generated electromagnetic field is measured.

On the other hand, as the electromagnetic field is provided to the sample region, a decomposition reaction of a sample is performed and free radicals are generated. That is, a magnetic resonance phenomenon in which electromagnetic waves are absorbed or emitted when a magnetic field is applied to electrons or an atomic nucleus is generated, and a characteristic of a material may be analyzed using the magnetic resonance principle. When free radicals are generated, the electromagnetic field is changed. The measuring unit 16 processes the signal amplified by the double lock-in amplifiers 11 and 12 to be output as a generating signal for measuring free radicals. In addition, in accordance with a change in the electromagnetic field of free radicals, intensity of a magnetic field of the electromagnetic field measured by the measuring unit 16 is changed. Therefore, the measuring unit 16 may measure free radicals based on the intensity of the measured magnetic field (S130).

The spectrum analyzing unit 15 measures and analyzes a spectrum of a frequency in accordance with a change in the electromagnetic field (S140). Information on free radicals as an electron without a pair may be obtained by a position and a form of a resulting spectrum.

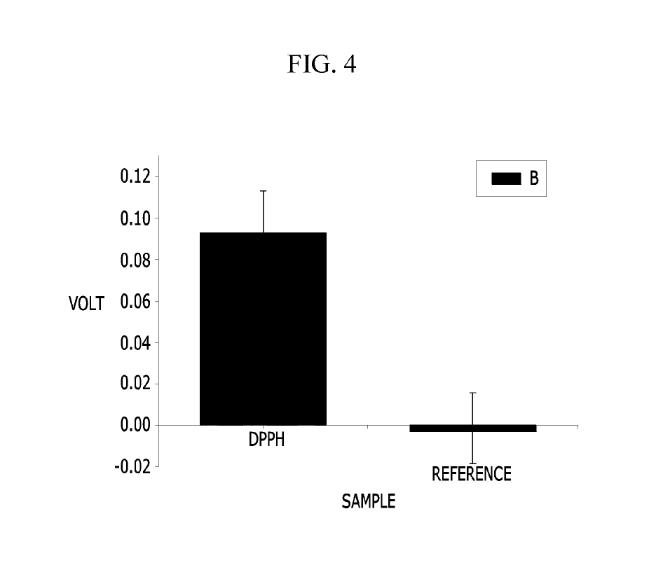

FIG. 4 is a graph illustrating free radicals measured using a measuring apparatus according to an exemplary embodiment of the present invention.

Here, in a state where DPPH (2,2-diphenyl-1-picrylhydrazil: Sigma-Aldrich) is filled in a glass tube having a diameter of 6 to 9 mm and a length of 7 to 9 cm to about 1 cm, an electromagnetic field is generated in a sample using the measuring apparatus 1 according to an exemplary embodiment of the present invention to obtain a signal for measuring free radicals and free radicals are measured based on the signal. DPPH is a solid radical and is a material commonly used for measuring free radicals. When a signal is obtained from the DPPH, the signal may be considered to be a signal obtained from free radicals.

As illustrated in FIG. 4, free radicals generated by the sample may be easily measured using the measuring apparatus 1 in which the double solenoid coil and the double lock-in amplifier are provided.

Particularly, free radicals are is measured by the double lock-in amplifier so that it is possible to reduce the number of modulation coils and amplifiers that are essential for electromagnetic field analyzing equipment such as conventional electron spin resonance (ESR) and nuclear magnetic resonance (NMR) apparatuses. Therefore, it is possible to simplify a structure of a measuring apparatus and to reduce manufacturing cost.

According to the above-described exemplary embodiment, unlike in the conventional ESR using resonance of electrons, according to the exemplary embodiment of the present invention, among electromagnetic characteristics of free radicals, a non-linear signal in an electromagnetic field is measured so that free radicals may be easily measured.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A measuring apparatus, comprising:
a signal generator for generating a first signal and a second signal having different frequencies;
a double solenoid coil for operating in accordance with the first signal and the second signal to generate an electromagnetic field and to provide the generated electromagnetic field as a sample;
a first amplifier for receiving a signal corresponding to the generated electromagnetic field to amplify and output the received signal;
a second amplifier for amplifying the signal output from the first amplifier to output the amplified signal; and
a measuring unit for receiving a signal from the second amplifier to measure the received signal.

2. The measuring apparatus of claim 1, wherein the first amplifier and the second amplifier form a double lock-in amplifier.

3. The measuring apparatus of claim 1, wherein the measuring unit measures free radicals generated by the sample in accordance with an electromagnetic field based on a signal corresponding to the electromagnetic field.

4. The measuring apparatus of claim 1, further comprising a spectrum analyzing unit for analyzing a frequency spectrum of a signal corresponding to an electromagnetic field generated by the double solenoid coil.

5. A measuring method, comprising:
a double solenoid coil operating in accordance with input first and second signals to generate an electromagnetic field and to provide the generated electromagnetic field as a sample;
receiving, amplifying, and outputting a signal corresponding to the generated electromagnetic field by a double lock-in amplifier; and
measuring free radicals generated by the sample in accordance with an electromagnetic field based on the signal output from the double lock-in amplifier.

6. The measuring method of claim 5, further comprising analyzing a frequency spectrum of a signal corresponding to an electromagnetic field generated by the double solenoid coil to analyze a state of free radicals.

7. The measuring method of claim 5, wherein the first signal and the second signal have different frequencies.
